(19) United States
(12) Patent Application Publication
(10) Pub. No.: US 2023/0250542 A1
(43) Pub. Date: Aug. 10, 2023

(54) ELECTRODE

(71) Applicant: NITTO DENKO CORPORATION, Osaka (JP)

(72) Inventors: Yuna SUGA, Osaka (JP); Motoki HAISHI, Osaka (JP); Mitsunobu TAKEMOTO, San Jose, CA (US)

(21) Appl. No.: 17/669,149

(22) Filed: Feb. 10, 2022

(51) Int. Cl. C25B 11/052; H01B 1/02; H01B 5/14; C23C 14/20; C23C 14/06; C23C 14/35; C25B 11/057; C25B 11/075

(52) U.S. Cl. CPC C25B 11/052; C23C 14/35; C23C 14/205; C23C 14/0605; C25B 11/057; C25B 11/075; H01B 1/02; H01B 5/14; C25B 3/26

(57) ABSTRACT

An electrode includes a substrate, a conductive carbon layer disposed on one surface in a thickness direction of the substrate, and copper particles. The conductive carbon layer includes an sp² bond and an sp³ bond. The copper particles are disposed in form of islands on one surface in the thickness direction of the conductive carbon layer and/or dispersed inside the conductive carbon layer.

### TECHNICAL FIELD

The present invention relates to an electrode.

### BACKGROUND ART

A method for conversion of carbon dioxide to ethanol by electrolysis is known. The electrolysis uses an electrode (electrocatalyst). An electrode including carbon nanospikes in form of a multilayer graphene structure and copper-containing nanoparticles located on the surface of the structure has been proposed (for example, see Patent Document 1).

In Patent Document 1, the carbon nanospikes are formed by chemical vapor deposition at 650° C.

### Citation List

### Patent Document

Patent Document 1: Japanese Translation of PCT International Application Publication No. 2019-516862

### SUMMARY OF THE INVENTION

### Problem to Be Solved by the Invention

An electrode is required to have a uniform quality.

In Patent Document 1, however, the carbon nanospikes of the electrode are formed by a high-temperature process. Thus, there is a disadvantage that the above-described requirement is not fulfilled.

The present invention provides an electrode having a uniform quality.

### Means for Solving the Problem

The present invention [1] includes an electrode including: a substrate; a conductive carbon layer disposed on one surface in a thickness direction of the substrate; and a copper material being at least one selected from the group consisting of copper, an alloy containing copper, and a compound containing copper, wherein the conductive carbon layer contains an sp² bond and an sp³ bond, and the copper material is disposed in form of islands on one surface in the thickness direction of the conductive carbon layer and/or dispersed inside the conductive carbon layer.

The present invention [2] includes the electrode described in [1], wherein a ratio of the number of the sp³ bonded atoms to a sum of the number of the sp² bonded atoms and the number of the sp³ bonded atoms is 0.35 or more.

The present invention [3] includes the electrode described in [1] or [2], further including: a metal underlying layer disposed between the substrate and the conductive carbon layer.

The present invention [4] includes the electrode described in any one of the above-described [1] to [3], wherein the material of the substrate is an organic material.

The present invention [5] includes the electrode described in any one of the above-described [1] to [4], being a cathode for electrolysis.

### Effects of the Invention

The electrode of the present invention has a uniform quality.

### BRIEF DESCRIPTION OF THE DRAWINGS

FIG. 1 is a cross-sectional view of one embodiment of the electrode of the present invention.

FIG. 2 illustrates a variation of the electrode.

### DESCRIPTION OF THE EMBODIMENT

### 1. One Embodiment of Electrode

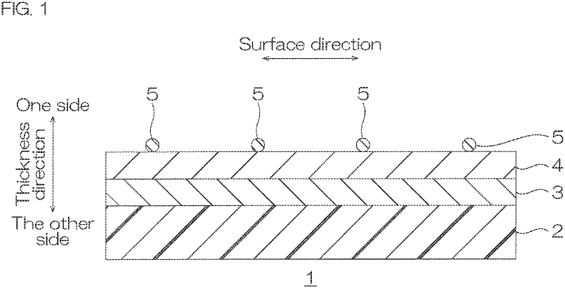

One embodiment of the electrode of the present invention is described with reference to FIG. 1. The electrode 1 has a thickness. The electrode 1 extends in a surface direction. The surface direction is orthogonal to a thickness direction. Specifically, the electrode 1 has a sheet shape. Sequentially toward one side in the thickness direction, the electrode 1 of the embodiment includes a substrate 2, a metal underlying layer 3, a conductive carbon layer 4, and copper particles 5 that exemplify a copper material. The electrode 1 preferably includes only the substrate 2, the metal underlying layer 3, the conductive carbon layer 4, and the copper particles 5.

### 1.1 Substrate 2

The substrate 2 is disposed on the other end in the thickness direction of the electrode 1. The substrate 2 forms the other surface in the thickness direction of the electrode 1. The substrate 2 extends in the surface direction. Examples of the material of the substrate 2 include inorganic materials and organic materials. Examples of the inorganic material include silicon and glass. Examples of the organic material include polyester, polyolefin, acryl, and polycarbonate. Examples of the polyester include polyethylene terephthalate (PET), polyethylene naphthalate, and polybutylene naphthalate.

Preferably an organic material, more preferably polyester, even more preferably PET is used as the material of the substrate 2. When the material of the substrate 2 is an organic material, the substrate 2 is a flexible film. When the substrate 2 is a flexible film, the electrode 1 has an excellent handleability. When the material of the substrate 2 is an organic material, the substrate 2 is easily damaged during the high temperature process for the formation of the copper particles 5. Consequently, the electrode 1 tends to be nonuniform in quality. On the other hand, as described below, the copper particles 5 of the present embodiment are formed by a low-temperature process. Thus, the substrate 2 made of an organic material has flexibility, and the handleability of the electrode 1 can be improved.

The substrate 2 has a thickness of, for example, 2 µm or more, preferably 20 µm or more, and, for example, 1000 µm or less, preferably 500 µm or less.

### 1.2 Metal Underlying Layer 3

The metal underlying layer 3 is disposed on one surface in the thickness direction of the substrate 2. The metal underlying layer 3 is in contact with the one surface in the thickness direction of the substrate 2. The metal underlying layer 3 extends in the surface direction. Examples of the metal underlying layer 3 include the Group 4 metal elements (titanium and zirconium), the Group 5 metal elements (vanadium, niobium, and tantalum), the Group 6 metal elements (chromium, molybdenum, and tungsten), the Group 7 metal elements (manganese), the Group 8 metal elements (iron), the Group 9 metal elements (cobalt), the Group 10 metal elements (nickel and platinum), the Group 11 metal elements (gold), the Group 12 metal elements (zinc), the Group 13 metal elements (aluminum and gallium), and the Group 14 metal elements (germanium and tin). These can be used singly or in combination. Preferably a Group 4 metal element, more preferably titanium is used as the material of the metal underlying layer 3. The metal underlying layer 3 has a thickness of, for example, 1 nm or more, preferably 3 nm or more, and, for example, 50 nm or less, preferably 35 nm or less.

### 1.3 Conductive Carbon Layer 4

The conductive carbon layer 4 is disposed on one surface in the thickness direction of the metal underlying layer 3. The conductive carbon layer 4 is in contact with the one surface in the thickness direction of the metal underlying layer 3. The conductive carbon layer 4 is disposed at one side of the substrate 2 through the metal underlying layer 3 in the thickness direction. In this manner, the metal underlying layer 3 intervenes between the substrate 2 and the conductive carbon layer 4. The conductive carbon layer 4 extends in the surface direction. The conductive carbon layer 4 has conductivity.

The conductive carbon layer 4 includes an sp² bond and an sp³ bond. Specifically, the conductive carbon layer 4 includes an sp² bonded atom and an sp³ bonded atom. More specifically, the conductive carbon layer 4 includes carbon having an sp² bond and carbon having an sp³ bond. In other words, the conductive carbon layer 4 has a graphite structure and a diamond structure. In this manner, the conductive carbon layer 4 has a uniform quality.

When the conductive carbon layer 4 is carbon nanospikes including only an sp² bond, the conductive carbon layer 4 is formed by a high-temperature process, and thus has a nonuniform quality.

In the conductive carbon layer 4, a ratio (sp³/sp³ + sp²) of the number of sp³ bonded atoms to the sum of the number of sp³ bonded atoms and the number of sp² bonded atoms is, for example, 0.10 or more, preferably 0.35 or more, more preferably 0.40 or more, even more preferably 0.45 or more, and, for example, 0.90 or less, preferably 0.75 or less, more preferably 0.50 or less.

Where the ratio (sp³/sp³ + sp²) of the number of the sp³ bonded atoms in the conductive carbon layer 4 is the above-described lower limit or more, ethanol production can be increased when the electrode 1 is used for electrolysis for conversion of carbon dioxide into ethanol.

Where the ratio (sp³/sp³ + sp²) of the number of the sp³ bonded atoms in the conductive carbon layer 4 is the above-described upper limit or less, the electrode 1 has conductivity and thus can be used as an electrode for electrolysis.

The ratio (sp³/sp³ + sp²) of the number of the sp³ bonded atoms in the conductive carbon layer 4 is measured using X-ray photoelectron spectroscopy.

The conductive carbon layer 4 is allowed to contain a trace of inevitable impurities other than oxygen.

The conductive carbon layer 4 has a thickness of, for example, 0.1 nm or more, preferably 1 nm or more, and, 100 nm or less, preferably 50 nm or less.

### 1.4 Copper Particles 5

The copper particles 5 are disposed at one end in the thickness direction of the electrode 1. The copper particles 5 are disposed on one surface in the thickness direction of the conductive carbon layer 4. In the embodiment, the copper particles 5 form a layer on the one surface of the conductive carbon layer 4 and form islands viewed from one side in the thickness direction. The copper particles 5 can form island shapes by forming aggregates. In such a case, the aggregates are individually scattered and separated from each other by an interval in the surface direction. The copper particles 5 each have an approximately spherical surface. The copper particles 5 can be used as a reduction catalyst for carbon dioxide. Specifically, the copper particles 5 can function as a catalyst for the electrolysis when carbon dioxide is converted into ethanol in the electrode 1.

A rate of the area of the copper particles 5 on the one surface in the thickness direction of the conductive carbon layer 4 is, for example, more than 0%, preferably 1% or more, more preferably 2% or more, and, for example, less than 100%, preferably 95% or less, more preferably 50% or less, even more preferably 10% or less.

The rate of the area of the copper particles 5 on the one surface of the conductive carbon layer 4 is calculated from a TEM image of the surface. A method of measuring the rate of the area of the copper particles 5 is described in detail in Examples below.

The dimensions of the copper particles 5 are not especially limited.

The electrode 1 has a thickness of, for example, 2 µm or more, preferably 20 µm or more, and, for example, 1000 µm or less, preferably 500 µm or less.

### 1.5 Method of Producing Electrode 1

Next, a method of producing the electrode 1 is described. In the method, the substrate 2 is prepared first. Next, the metal underlying layer 3, the conductive carbon layer 4, and the copper particles 5 are formed on the substrate 2 sequentially toward one side in the thickness direction.

For example, a dry method, preferably sputtering, more preferably magnetron sputtering is used to form the metal underlying layer 3 on the one surface in the thickness direction of the substrate 2. The magnetron sputtering includes DC magnetron sputtering. The sputtering uses, for example, the above-described metal as the target material. The sputtering uses, for example, a noble gas, preferably argon as the sputtering gas. The electricity (power) applied to the target material and the pressure of the sputtering gas are appropriately set. The sputtering is carried out at a temperature of, for example, 200° C. or less, preferably 150° C. or less, more preferably 125° C. or less. The above-described temperature is a film deposition temperature and a surface temperature of the film deposition substrate or film deposition roll. Where the film deposition temperature is the above-described upper limit or less, the damage to the substrate 2 is suppressed and consequently the quality of the electrode 1 is uniformed even when the material of the substrate 2 is an organic material.

For example, a dry method, preferably sputtering, more preferably magnetron sputtering is used to form the conductive carbon layer 4 on the one surface in the thickness direction of the metal underlying layer 3. The magnetron sputtering includes DC magnetron sputtering and unbalanced magnetron sputtering. The sputtering uses, for example, a sintered carbon as the target material. The sputtering uses, for example, a noble gas, preferably argon as the sputtering gas. The electricity applied to the target material and the pressure of the sputtering gas are appropriately set. The sputtering is carried out at a temperature of, for example, 200° C. or less, preferably 150° C. or less, more preferably 125° C. or less. The above-described temperature is a film deposition temperature and a surface temperature of the film deposition substrate or film deposition roll. Where the film deposition temperature is the above-described upper limit or less, the damage to the substrate 2 is suppressed and consequently the quality of the electrode 1 is uniformed even when the material of the substrate 2 is an organic material.

For example, a dry method, preferably sputtering, more preferably magnetron sputtering is used to form the copper particles 5 on a part of the one surface in the thickness direction of the conductive carbon layer 4. The magnetron sputtering includes DC magnetron sputtering. The sputtering uses, for example, copper as the target material. The sputtering uses, for example, a noble gas, preferably argon as the sputtering gas. The pressure of the sputtering gas is appropriately set. The sputtering is carried out at a temperature of, for example, 200° C. or less, preferably 150° C. or less, more preferably 125° C. or less. The above-described temperature is a film deposition temperature and a surface temperature of the film deposition substrate or film deposition roll. Where the film deposition temperature is the above-described upper limit or less, the damage to the substrate 2 is suppressed and consequently the quality of the electrode 1 is uniformed even when the material of the substrate 2 is an organic material.

### 1.6 Use of Electrode 1

Next, the use of the electrode 1 is described. Examples of the use of the electrode 1 include electrolysis and an electrochemical measurement. Preferably the electrode 1 is used for electrolysis. Examples of the electrolysis include a reaction in which the carbon dioxide dissolved in the electrolytic solution is subjected to electrolysis and finally converted into ethanol. When being used for the above-described electrolysis, the electrode 1 functions as the cathode. Such a reaction is described in, for example, Japanese Translation of PCT International Application Publication No. 2019-516862.

Next, an electrolysis system including the electrode 1 is described. The electrolysis system includes the electrode 1 as the cathode, an anode, and a reference electrode.

The anode is, for example, Pt. The reference electrode is, for example, Ag/AgCl. A power source is connected to the electrode 1, the anode, and the reference electrode.

To convert carbon dioxide into ethanol using the electrolysis system, an electrolytic solution is prepared first. The electrolytic solution includes water and an electrolyte. Examples of the electrolyte include a hydroxide of an alkali metal (such as KOH).

Next, the above-described electrode 1, anode, and reference electrode are immersed in the electrolytic solution.

Subsequently, carbon dioxide is made bubbling in the electrolytic solution.

Simultaneously, electricity is applied to the electrode 1 and the anode.

In this manner, carbon dioxide is converted into ethanol in the electrolytic solution.

### 2. Operations and Effects of One Embodiment

The electrode 1 includes the conductive carbon layer 4 containing an sp² bond and an sp³ bond, and thus has a uniform quality in comparison with an electrode 1 including a conductive carbon layer 4 containing only an sp² bond.

Specifically, the conductive carbon layer 4 of Patent Document 1, which contains only an sp² bond, produces a carbon nanospike structure and is formed by chemical vapor deposition at 650° C., namely, a high film deposition temperature in order to function as an electrode. Thus, the substrate 2 made of an organic material is easily deteriorated and cannot maintain a film shape, and consequently cannot maintain a form used as the electrode 1.

Contrarily, the electrode 1 of the present embodiment includes the conductive carbon layer 4 containing an sp² bond and an sp³ bond, and thus the conductive carbon layer 4 is formed by sputtering at a relatively low film deposition temperature (for example, 200° C. or less). As a result, even when the substrate 2 is made of an organic material, the deterioration is suppressed and the quality is uniformed. Therefore, the copper particles 5 are stably formed and consequently the quality of the electrode 1 is uniformed.

Where the ratio of the number of the sp³ bonded atoms to the sum of the number of the sp² bonded atoms and the number of the sp³ bonded atoms is 0.35 or more in the electrode 1 of the present embodiment, ethanol production can be increased when the electrode 1 is used for the electrolysis for conversion of carbon dioxide into ethanol.

### 3. Variations

In each of the variations, the same members and steps as in one embodiment will be given the same numerical references and the detailed description thereof will be omitted. Further, the variations can have the same operations and effects as those of one embodiment unless especially described otherwise. Furthermore, one embodiment and the variations can appropriately be combined.

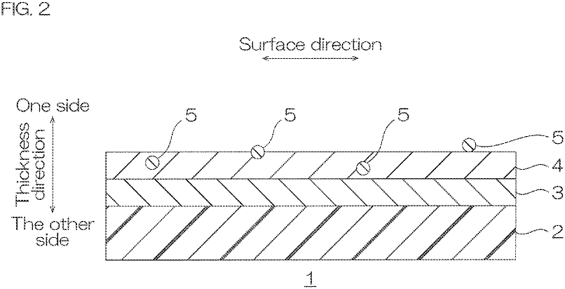

As illustrated in FIG. 2, the copper particles 5 exist on the one surface of the conductive carbon layer 4 and simultaneously exist and are dispersed inside the conductive carbon layer 4. The copper particles 5 existing on the one surface of the conductive carbon layer 4 may partially be embedded in the conductive carbon layer 4. The method of producing the electrode 1 illustrated in FIG. 2 uses a sintered carbon and copper as the target material to form the conductive carbon layer 4 and the copper particles 5.

Not illustrated, the electrode 1 does not include a metal underlying layer 3, and includes only a substrate 2, a conductive carbon layer 4, and copper particles 5. Preferably, the electrode 1 includes a metal underlying layer 3. This improves the adhesion of the conductive carbon layer 4 and/or, when the substrate 2 is made of PET, suppresses the outgassing from the substrate 2.

The copper particles 5 are described above as an example of the copper. However, for example, a copper continuous film having a penetrating hole may be used.

Not only the copper but also an alloy containing copper or a compound containing copper may be used. Examples of the alloy include a copper-nickel alloy and a copper-tin alloy. Examples of the compound include copper oxide.

In other words, in place of the copper particles 5, copper-nickel alloy particles and copper-tin alloy particles are used. Alternatively, copper oxide particles are used.

### EXAMPLES

The present invention is described in more detail with reference to Examples and Comparative Examples. The present invention is not limited to Examples and Comparative Examples in any manner. The specific numeral values used in the description below, such as mixing ratios (contents), physical property values, and parameters can be replaced with the corresponding mixing ratios (contents), physical property values, parameters in the above-described “DESCRIPTION OF THE EMBODIMENT”, including the upper limit values (numeral values defined with “or less”, and “less than”) or the lower limit values (numeral values defined with “or more”, and “more than”). The “parts” and “%” are based on mass unless otherwise specified.

### Example 1

A substrate 2 made of PET was prepared. Next, a metal underlying layer 3 made of titanium and having a thickness of 7 nm, a conductive carbon layer 4 having a thickness of 10 nm, and copper particles 5 were formed on the substrate 2 toward one side in the thickness direction. In this manner, an electrode 1 was produced. Each of the metal underlying layer 3, the conductive carbon layer 4, and the copper particles 5 were formed by a DC magnetron sputtering using a sputtering device. The conditions for the DC magnetron sputtering are shown in Table 1. All the DC magnetron sputterings were carried out at a film deposition temperature of 25° C. (room temperature) or less. The ratio of (sp³/sp³ + sp²) of the number of the sp³ bonded atoms in the conductive carbon layer 4 was 0.35 by the measurement using X-ray photoelectron spectroscopy.

### Comparative Example 1

In accordance with the method of Example 1, an electrode 1 that did not include copper particles 5 and included a substrate 2, a metal underlying layer 3, and a conductive carbon layer 4 was produced.

### Example 2

A substrate 2 made of PET was prepared. Next, a metal underlying layer 3 made of titanium and having a thickness of 7 nm, a conductive carbon layer 4 having a thickness of 10 nm, and copper particles 5 were formed on the substrate 2 toward one side in the thickness direction, thereby producing an electrode 1. Each of the metal underlying layer 3 and the copper particles 5 were formed by a DC magnetron sputtering using a sputtering device. The conductive carbon layer 4 was formed by an unbalanced magnetron sputtering using a sputtering device. At the time, a DC bias of 75 V was applied between the substrate 2 and the target material made of a sintered carbon. The conditions for the sputtering are shown in Table 2. All the unbalanced DC magnetron sputterings were carried out at a film deposition temperature of 25° C. (room temperature) or less. The ratio of (sp³/sp³ + sp²) of the number of the sp³ bonded atoms in the conductive carbon layer 4 was 0.45 by the measurement using X-ray photoelectron spectroscopy.

### Comparative Example 2

In accordance with the method of Example 2, an electrode 1 that did not include copper particles 5 and included a substrate 2, a metal underlying layer 3, and a conductive carbon layer 4 was produced.

### Comparative Example 3

An electrode 1 was produced in the same manner as in Example 1. However, the conductive carbon layer 4 and copper particles 5 were formed in accordance with the method described in Example 1 of Japanese Translation of PCT International Application Publication No. 2019-516862. Specifically, a CVD method was carried out at 650° C.

### <Evaluation>

The following properties of the electrode 1 of each of Examples and Comparative Examples were evaluated. The results are shown in Table 3.

### Damage to Substrate

The damage to the substrate 2 by heating was assessed. Damage to the substrate 2 was not confirmed in Examples 1 and 2 and Comparative Examples 1 and 2. Contrarily, damage to the substrate 2 by heating was confirmed in Comparative Example 3.

### Rate of Area of Copper Particles 5 on One Surface of Conductive Carbon Layer 4

The rate of the area of the copper particles 5 on the one surface of the conductive carbon layer 4 was calculated from a TEM image of the surface. The range of the image was from the minimum phase difference to the maximum phase difference. The bright parts of the phase image were deemed the copper particles 5 and the dark parts thereof were deemed the conductive carbon layer 4. The image was binarized by brightness using image analysis software (WinROOF). The distribution of the bright parts in the image was obtained. The bright parts to 90% of the maximum frequency were deemed the conductivity carbon regions and the parts with a brightness lower than those of the bright parts were deemed the copper regions to binarize the image. The rate of the area of the copper particles 5 on the one surface of the conductive carbon layer 4 was calculated from the binarized image obtained using the software. Because the damage to the substrate 2 by heating was confirmed, the rate of the area of the copper particles 5 of Comparative Example 3 was not evaluated.

### Electrolysis of Carbon Dioxide and Ethanol Production

An insulating tape having a 2 cm² hole was bonded to the one surface of the electrode 1. The carbon thin film electrode was immersed in 0.1 M of a KOH electrolytic solution and connected to a potentiostat (manufactured by HOKUTO DENKO CORPORATION, HZ5000) as a power source. Similarly, the reference electrode (Ag/AgCl) and the anode (Pt) were also immersed in 0.1 M of the KOH electrolytic solution and connected to the potentiostat.

Subsequently, carbon dioxide was sent to the KOH electrolytic solution and made bubbling for 30 minutes. Thereafter, an electric potential of -1.4 V (vs Ag/AgCl) was applied for one hour for the electrolysis of carbon dioxide.

Thereafter, the amount of ethanol produced in the electrolytic solution was measured with GC-MS (manufactured by SHIMADZU CORPORATION, GCMS-QP 2010 plus). Specifically, a cationic cartridge was passed through the electrolytic solution. The solution was used for the measurement of the amount of ethanol with the GC-MS.
Column: WAX based
Injection temperature: 250° C.
Injection: split (5:1)
Injection amount: 1 µL
Carrier gas flow: 1 mL/min
Ionization method: Electron ionization
Identification m/z: m/z 31 (SIM mode)

Because the damage to the substrate 2 by heating was confirmed, the ethanol production of Comparative Example 3 was not evaluated.

TABLE 1

| | Metal underlying layer | Conductive carbon layer | Copper particles |
|---|---|---|---|
| Target material | Titanium | Sintered carbon | Copper |
| Argon gas pressure (Pa) | 0.2 | 0.4 | 0.3 |
| Target power (W/cm²) | 3.33 | 3.33 | 0.13 |

TABLE 2

| | Metal underlying layer | Conductive carbon layer | Copper particles |
|---|---|---|---|
| Target material | Titanium | Sintered carbon | Copper |
| Argon gas pressure (Pa) | 0.2 | 0.6 | 0.3 |
| Target power (W/cm²) | 0.54 | 8.7 | 0.13 |

TABLE 3

| | Conductive carbon layer | Copper particles | | Catalyst evaluation | Quality evaluation |
|---|---|---|---|---|---|
| | sp³/(sp² + sp³) | Presence/Absence | Rate of area of copper particles (%) | ethanol production (× 10⁻⁹ mol) | Damage to substrate |
| Example 1 | 0.35 | Presence | 3 | 0.4 | Not confirmed |
| Example 2 | 0.45 | Presence | 3 | 1.8 | Not confirmed |
| Comparative Example 1 | 0.35 | Absence | 0 | 0 | Not confirmed |
| Comparative Example 2 | 0.45 | Absence | 0 | 1 | Not confirmed |
| Comparative Example 3 | 0.00 | Presence | - | - | Confirmed |

Description of Reference Numerals

| | |
|---|---|
| 1 | electrode |
| 2 | substrate |
| 3 | metal underlying layer |
| 4 | conductive carbon layer |
| 5 | copper particles |

1. An electrode comprising:
a substrate;
a conductive carbon layer disposed on one surface in a thickness direction of the substrate; and
a copper material being at least one selected from the group consisting of copper, an alloy containing copper, and a compound containing copper, wherein
the conductive carbon layer contains an sp² bond and an sp³ bond, and
the copper material is disposed in form of islands on one surface in the thickness direction of the conductive carbon layer and/or dispersed inside the conductive carbon layer.

2. The electrode according to claim 1, wherein a ratio of the number of the sp³ bonded atoms to a sum of the number of the sp² bonded atoms and the number of the sp³ bonded atoms is 0.35 or more.

3. The electrode according to claim 1, further comprising:
a metal underlying layer disposed between the substrate and the conductive carbon layer.

4. The electrode according to claim 2, further comprising:
a metal underlying layer disposed between the substrate and the conductive carbon layer.

5. The electrode according to claim 1, wherein the material of the substrate is an organic material.

6. The electrode according to claim 2, wherein the material of the substrate is an organic material.

7. The electrode according to claim 3, wherein the material of the substrate is an organic material.

8. The electrode according to claim 4, wherein the material of the substrate is an organic material.

9. The electrode according to claim 1, being a cathode for electrolysis.

10. The electrode according to claim 2, being a cathode for electrolysis.

11. The electrode according to claim 3, being a cathode for electrolysis.

12. The electrode according to claim 4, being a cathode for electrolysis.

13. The electrode according to claim 5, being a cathode for electrolysis.

14. The electrode according to claim 6, being a cathode for electrolysis.

15. The electrode according to claim 7, being a cathode for electrolysis.

16. The electrode according to claim 8, being a cathode for electrolysis.
